(19) United States
(12) Patent Application Publication
(10) Pub. No.: US 2026/0068655 A1
(43) Pub. Date: Mar. 5, 2026

(54) SUPER VIA CONNECTION AS CAPACITOR AND THERMAL CONDUCTOR

(71) Applicant: INTERNATIONAL BUSINESS MACHINES CORPORATION, Armonk, NY (US)

(72) Inventors: Tsung-Sheng Kang, Ballston Lake, NY (US); Tao Li, Slingerlands, NY (US); Ruilong Xie, Niskayuna, NY (US); Eric Miller, Albany, NY (US)

(21) Appl. No.: 18/823,207

(22) Filed: Sep. 3, 2024

(51) Int. Cl. H01L 23/522; H01L 23/367; H01L 23/528; H01L 27/06; H01L 29/06; H01L 29/423; H01L 29/775; H01L 29/786

(52) U.S. Cl. CPC H01L 23/5223; H10D 1/692; H10D 84/811; H10D 30/43; H10D 30/6735; H10D 30/6757; H10D 62/121

(57) ABSTRACT

A semiconductor device includes a back end of the line region on a frontside of the semiconductor device. A backside interconnect metallization layer is on a backside of the semiconductor device. A thermal conductivity channel is disposed between the back end of the line region and the backside interconnect metallization layer. The thermal conductivity channel includes a frontside super via and a backside super via connected by a contact therebetween.

### BACKGROUND

The present invention generally relates to semiconductor devices and processing methods, and more particularly to semiconductor structures with frontside to backside structures that enhance thermal conductivity.

Power is consumed when devices are active. Heat is produced when power is dissipated in devices and along wires. Heat dissipation is an important consideration during semiconductor device fabrication and during semiconductor device operation. Produced heat needs to be dissipated effectively from where the heat is being produced. Heat dissipation becomes more challenging as transistor density increases. To improve conductive heat transfer rate, energy needs to be directed along a path that dispels the heat without increasing heat in already elevated temperature regions.

While a heatsink can dissipate heat, the path in which heat flows through a device is just as important, as a heat sink alone can cause additional problems if proper analysis is not performed. Considerations such as air flow, structural design, heat flow, etc. are employed to mitigate and spread heat through a device. Unlike electrical conductivity, where there are orders of magnitude differences between a conductor and an insulator, thermal conductivity is more limited as differences between different materials are less pronounced. Therefore, paths of thermal conductivity are more difficult to design within a device structure.

Therefore, a need exists for improving heat transfer through a device to enhance device performance.

### SUMMARY

In accordance with an embodiment of the present invention, a semiconductor device includes a back end of the line region on a frontside of the semiconductor device. A backside interconnect metallization layer is on a backside of the semiconductor device. A thermal conductivity channel is disposed between the back end of the line region and the backside interconnect metallization layer. The thermal conductivity channel includes a frontside super via and a backside super via connected by a contact therebetween.

In accordance with another embodiment of the present invention, a semiconductor device includes a back end of the line region on a frontside of the semiconductor device and a backside interconnect metallization layer on a backside of the semiconductor device. A thermal conductivity channel is disposed between the back end of the line region and the backside interconnect metallization layer. The thermal conductivity channel includes a frontside super via and a backside super via connected by a contact therebetween. A capacitor includes the thermal conductivity channel as a first electrode and metal lines traversed by the thermal conductivity channel as a second electrode.

In accordance with another embodiment of the present invention, a semiconductor device includes a back end of the line region on a frontside of the semiconductor device and a backside interconnect metallization layer on a backside of the semiconductor device. A thermal conductivity channel is disposed between the back end of the line region and the backside interconnect metallization layer. The thermal conductivity channel includes a frontside super via and a backside super via connected by a contact therebetween. The thermal conductivity channel is disposed within a thermal conductor region adjacent to a logic region to channel heat to the back end of the line region and the backside interconnect metallization layer. A capacitor includes a first electrode as the thermal conductivity channel, metal lines traversed by the thermal conductivity channel as a second electrode and a capacitor dielectric disposed within indentations of the metal lines and adjacent to the thermal conductivity channel.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views of a thermal conductor region and a logic region of a semiconductor device where the thermal conductor region and the logic region have a same structure for a single layer of transistors, in accordance with an embodiment of the present invention;

FIG. 2 shows cross-sectional views of the thermal conductor region and the logic region of the semiconductor device having a single diffusion barrier formed in the thermal conductor region, in accordance with an embodiment of the present invention;

FIG. 3 shows cross-sectional views of the thermal conductor region and the logic region of the semiconductor device having a contact formed in the thermal conductor region, in accordance with an embodiment of the present invention;

FIG. 4 shows cross-sectional views of the thermal conductor region and the logic region of the semiconductor device having a back end of the line structure formed and opened to expose the contact in the thermal conductor region, in accordance with an embodiment of the present invention;

FIG. 5 shows cross-sectional views of the thermal conductor region and the logic region of the semiconductor device having a capacitor dielectric formed in indentations of metal lines in the thermal conductor region, in accordance with an embodiment of the present invention;

FIG. 6 shows cross-sectional views of the thermal conductor region and the logic region of the semiconductor device having a frontside super via formed and remaining portions of the back end of the line structures formed, in accordance with an embodiment of the present invention;

FIG. 7 shows cross-sectional views of the thermal conductor region and the logic region of the semiconductor device after the semiconductor device is flipped and a substrate removed, in accordance with an embodiment of the present invention;

FIG. 8 shows cross-sectional views of the thermal conductor region and the logic region of the semiconductor device after a semiconductor layer is removed and replaced with a backside interlayer dielectric, in accordance with an embodiment of the present invention;

FIG. 9 shows cross-sectional views of the thermal conductor region and the logic region of the semiconductor device after a backside interconnect layer of backside power distribution network is formed and opened up to expose a sacrificial placeholder in the thermal conductor region, in accordance with an embodiment of the present invention;

FIG. 10 shows cross-sectional views of the thermal conductor region and the logic region of the semiconductor device after a backside interconnect layer or backside power distribution network is formed and opened up to expose a sacrificial placeholder in the thermal conductor region, in accordance with an embodiment of the present invention;

FIG. 11 shows cross-sectional views of the thermal conductor region and the logic region of the semiconductor device having a capacitor dielectric formed in indentations of metal lines in the thermal conductor region, in accordance with an embodiment of the present invention;

FIG. 12 shows cross-sectional views of the thermal conductor region and the logic region of the semiconductor device having the sacrificial placeholder and a source/drain region removed in the thermal conductor region, in accordance with an embodiment of the present invention;

FIG. 13 shows cross-sectional views of the thermal conductor region and the logic region of the semiconductor device having a thermal conductive channel formed in the thermal conductor region, in accordance with an embodiment of the present invention;

FIG. 14 shows cross-sectional views of the thermal conductor region and the logic region of a semiconductor device having stacked field effect transistors after the semiconductor device is flipped and a substrate removed and replaced with a backside interlayer dielectric, in accordance with an embodiment of the present invention;

FIG. 15 shows cross-sectional views of the thermal conductor region and the logic region of the semiconductor device after a backside interconnect layer or backside power distribution network is formed and opened up to expose a sacrificial placeholder in the thermal conductor region, in accordance with an embodiment of the present invention;

FIG. 16 shows cross-sectional views of the thermal conductor region and the logic region of the semiconductor device having a capacitor dielectric formed in indentations of metal lines in the thermal conductor region, in accordance with an embodiment of the present invention;

FIG. 17 shows cross-sectional views of the thermal conductor region and the logic region of the semiconductor device having the sacrificial placeholder and source/drain regions removed in the thermal conductor region, in accordance with an embodiment of the present invention; and

FIG. 18 shows cross-sectional views of the thermal conductor region and the logic region of the semiconductor device having a thermal conductive channel formed in the thermal conductor region, in accordance with an embodiment of the present invention.

### DETAILED DESCRIPTION

In accordance with embodiments of the present invention, devices and methods are described which include a super via chain or thermal conductivity channel that passes between a frontside to a backside of a semiconductor device. In an embodiment, the thermal conductivity channel includes a frontside super via and a backside super via, which are joined in a middle portion of the semiconductor devices by contacts and conductors formed therebetween. The super via chain or thermal conductivity channel can extend between back end of the line (BEOL) structurers on the frontside and a backside power distribution network (BSPDN) or backside interconnect metallization layer on the backside. In an embodiment, a thermal conductor region, where the super via chain is located, can have its position determined based on heat transfer needs. In one example, the thermal conductor region is placed adjacent to or within a logic region where transistor devices or other heat producing devices are located. By providing better thermal conductivity, better device performance can be achieved. The super via chain includes high thermally conductive materials to provide a heat transfer path through a center portion of the semiconductor device to permit heat dissipation or over a distributed area of the BEOL structures and the BSPDN.

The frontside and the backside super vias form extreme skip vias passing through a plurality of layers to form a thermal conductivity channel. In an embodiment, the thermal conductivity channel can also be leveraged to form a metal-insulator-metal (MIM) capacitor when the thermal conductivity channel passes through metal levels. In this way, the thermal conductivity channel can act as a first capacitor electrode and the metal layers can act as a second electrode (or many second electrodes). The frontside to backside super via chain can provide a large capacitor as well as a thermal conductor to better utilize device real estate.

Heat transfer simulations show that for bonded wafers with a BSPDN, heat generated at a transistor level is not easily dissipated. In accordance with embodiments of the present invention, the thermal conductivity channel can help dissipate heat from the transistor level and the BEOL structures to the BSPDN side to remove excess heat.

The thermal conductivity channel can include features that are fabricated during process steps of logic device portions. In this way, special process steps can be avoided in the fabrication of the thermal conductivity channel. Although logic portions are depicted and described, it should be understood that other device region types are contemplated that can include other than logic devices. The present embodiments are applicable to any device were heat dissipation is needed.

In some embodiments, portions of the thermal conductivity channel can be formed in different process steps to enable different thicknesses and types of dielectric materials for capacitor structures between, e.g., a frontside and backside of the device. In addition, different conductive materials can be employed for different portions of the thermal conductivity channel.

In other embodiments, methods for forming a semiconductor device can include formation of front end of the line (FEOL) devices including gates, source/drain regions, etc. In a thermal conductor region, single diffusion breaks (SDB) are formed on opposing sides of a source/drain region, and an interlayer dielectric (ILD) is formed over the device. A contact etch is performed to open a contact opening and expose the source/drain region. A contact is formed in the contact opening. Processing continues, and after the formation of BEOL structures on the frontside of the device, an etch process is employed to etch through BEOL metal layers to form a trench. The etch continues to laterally recess exposed metal lines within the trench. A dielectric refill is performed into the recessed regions. A metallization process is performed to form a frontside super via in contact with the contact. A backside of the device is processed to form backside metal layers. A backside ILD is formed. An etch process etches through the backside layers and through the source/drain region. This is followed by a lateral recess into exposed metal layers to form indentations. The indentations are refilled with dielectric material. A backside super via is formed by metallization from the backside and connects to the contact to form a thermal conductivity channel. A MIM capacitor is also formed where the refill dielectric acts as an insulator between the metal of the thermal conductivity channel and the metal lines adjacent to the refill dielectric.

While illustrative embodiments will be described in terms of nanosheet devices, embodiments of the present invention can be applied to other device types including but not limited to fin devices, forksheet devices, stacked field effect transistor devices, etc.

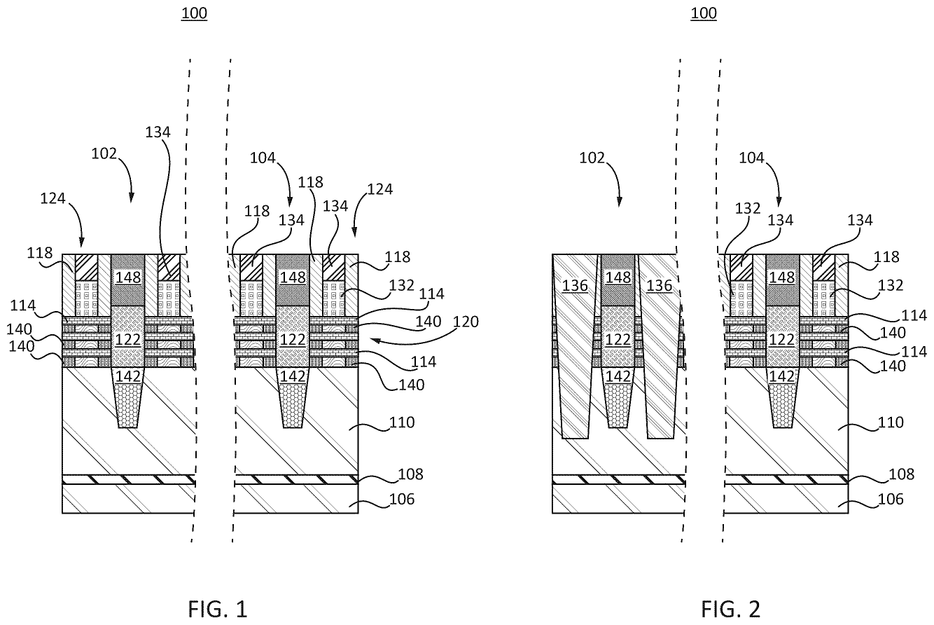

Referring now to the drawings in which like-numerals represent the same or similar elements and initially to FIG. 1, devices and methods for manufacturing a nanosheet field effect transistor (FET) device are shown in accordance with embodiments of the present invention.

A wafer 100 includes a substrate 106 on which the FET device will be fabricated. FIG. 1 depicts a cross-sectional view that cuts along an active region through a thermal conductor region 102 and a logic region 104 on the wafer 100 or device. The cross-section cuts through source/drain (S/D) regions 122 and gate structure 124 for transistor devices. Transistors can include N-type field effect transistors (NFETs) and/or P-type field effect transistors (PFETs).

The substrate 106 can have a single layer or multiple layers on which the FET device will be fabricated. The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In an embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

Shallow trench isolation (STI) or STI regions (not shown) can be formed in trenches etched in the semiconductor layer 110. STI regions can be formed by depositing a dielectric material, such as, e.g., a nitride, an oxide or other suitable materials.

A layer stack 120 or stacks are applied to or formed on the semiconductor layer 110. In an embodiment, one or more nanosheets (NS) are applied to the semiconductor layer 110. In another embodiment, the layer stack 120 can be epitaxially grown using different chemistries to form layers having different properties.

In an embodiment, the layer stack 120 of the nanosheet is processed to form channel layers 114 for FETs from alternating layers of the nanosheet. The other layers (semiconductor layers) of the nanosheet are removed but are employed for forming inner spacers 140. The inner spacers 140 and spacers 118 include a dielectric material, e.g., a nitride or an oxide. The inner spacers 140 can be formed by laterally etching the nanosheet layer and then filling the recess with a dielectric material. The inner spacers 140 can be formed by filling recesses where nanosheet layers were removed (by etching) with a dielectric material, e.g., SiBCN, SiCN or other suitable dielectric materials. Remaining portions of the nanosheet layer that were recessed for the inner spacers 140 are removed to expose the channel layers 114.

Source/drain regions 122 can be grown using an epitaxial growth process using the channel layer 114 and/or the semiconductor layer 110 (directly or using sacrificial placeholders 142) to initiate crystal growth. Source/drain regions 122 are formed on sacrificial placeholders 142. The semiconductor layer 110 is recessed to form trenches, e.g., by reactive ion etching (RIE). Within the trenches recessed into the semiconductor layer 110, the sacrificial placeholder 142 is formed. The sacrificial placeholder 142 can be epitaxially grown in the trenches of semiconductor layer 110. The sacrificial placeholder 142 can include SiGe or other epitaxial grown material that can be selectively removed relative to the semiconductor layer 110.

The source/drain regions 122 can include Si or SiGe. In an embodiment, the source/drain regions 122 can be designated as P-type or N-type devices. For example, if the source/drain regions 122 include N-type devices then the source/drain regions 122 can include Si. In another example, if the source/drain regions 122 include P-type devices then the source/drain regions 122 can include SiGe. The source/drain regions 122 can be appropriately doped during their formation. For example, the source/drain regions 122 can be doped by introducing p dopants (e.g., B, Ga, etc.) during epitaxial formation. Similarly, the source/drain regions 122 can be doped by introducing n dopants (e.g., P, As, etc.) during epitaxial formation. In some embodiments, a dummy gate material 132 is first employed in gate structures 124. A dielectric cap 134 (e.g., nitride) is formed on the dummy gate material 132.

An interlayer dielectric (ILD) 148 is deposited over the wafer 100. The ILD 148 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The ILD 148 can be deposited using chemical vapor deposition (CVD), although other deposition methods can be employed. The ILD 148 is planarized, e.g., by chemical mechanical polishing (CMP).

Referring to FIG. 2, the logic region 104 is blocked off so that processing can be performed in the thermal conductor region 102. An etch mask is patterned over the thermal conductor region 102 and an etch process (e.g., RIE) is performed to open up trenches by removing the gate structures 124 from the thermal conductor region 102. A dielectric material is deposited and a planarization process (e.g., chemical mechanical polishing (CMP)) is performed to form single diffusion barriers (SDB) 136 adjacent to the source/drain region 122 in the thermal conductor region 102. The SDB 136 can include any suitable dielectric material (e.g., an oxide or a nitride). The SDB 136 can be deposited by a CVD process, although any suitable deposition process can be employed.

Referring to FIG. 3, the dielectric cap 134 and the dummy gate material 132 are removed and a gate dielectric layer (not shown) is deposited to cover the channel layers 114. The gate dielectric layer can be formed by, e.g., chemical wet processes, CVD and/or atomic layer deposition (ALD). Suitable examples of the gate dielectric layer can include a silicon oxide interface layer followed by a high-K dielectric oxide that can include, but is not limited to: Al₂O₃, ZrO₂, HfO₂, Ta₂O₃, TiO₂ and combinations thereof.

A gate electrode 116 is formed over the gate dielectric layer and fills spaces between the channel layers 114 that the dummy gates once occupied. This process is known as a replacement metal gate (RMG) process to form High-K Metal Gate (HKMG) structures for selectively activating FETs. The gate electrode 116 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate conductor can be deposited by CVD, plasma enhanced CVD (PECVD), ALD or other suitable deposition process.

An interlayer dielectric (ILD) 150 is deposited over the wafer 100. The ILD 150 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The ILD 150 can be deposited using CVD, although other deposition methods can be employed. The ILD 150 is planarized, e.g., by CMP.

The ILD 150 is patterned by forming an etch mask and etching (e.g., RIE) contact openings in the ILD 150. The patterning of the ILD 150 is concurrently performed in the thermal conductor region 102 and the logic region 104. Middle of the line (MOL) contacts 152 are formed in the thermal conductor region 102 and the logic region 104 by a conductive fill to make connections with the source/drain regions 122 (and/pr the gate electrode 116) from a top or frontside of the wafer 100. Prior to the conductive fill, a silicide liner (not shown), such as Ti, Ni, NiPt can be deposited first, then a diffusion barrier (not shown) can be formed. The diffusion barrier can include, e.g., TiN, TaN, or similar materials. The silicide liner and the diffusion barrier can be deposited in the trench or hole (e.g., by ALD). The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the contacts 152.

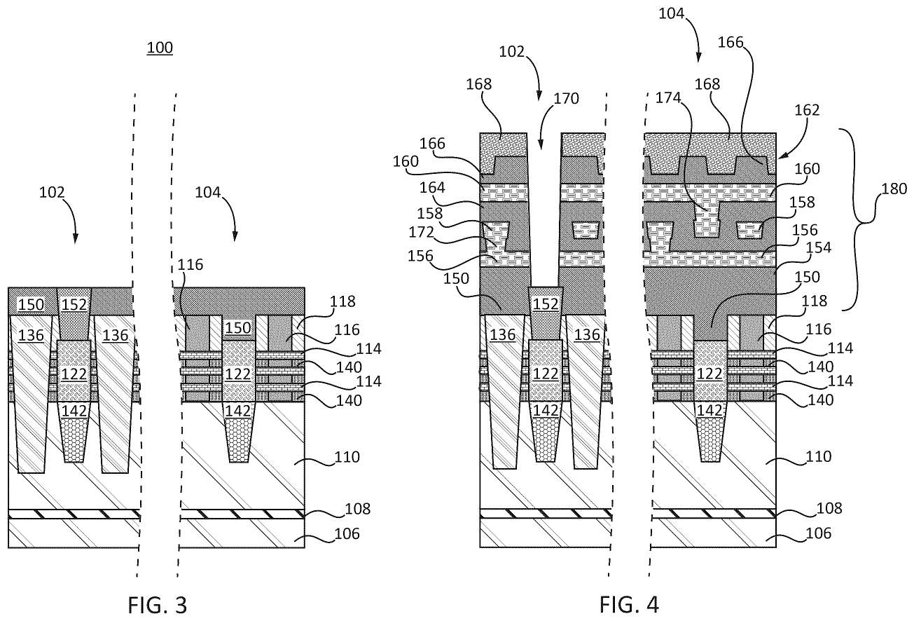

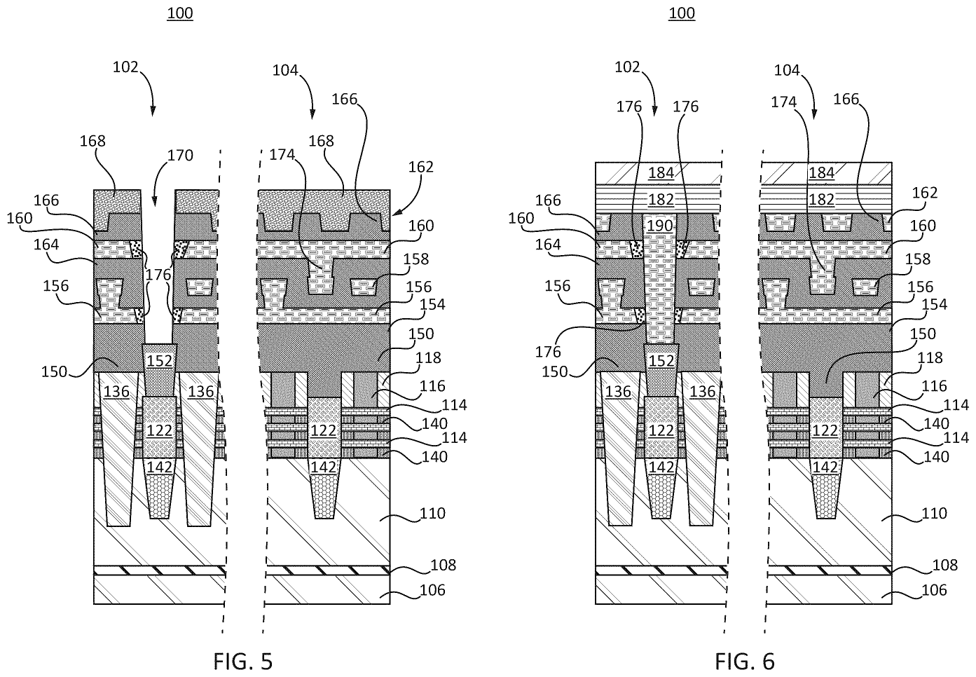

Referring to FIG. 4, BEOL structures are now formed. An additional dielectric layer 154 is formed on the ILD 150. The additional dielectric layer 154 is deposited and patterned to form trenches in which metal lines 156 are formed. The dielectric layer 154 can include a same or similar material as that of ILD 150. A diffusion barrier can be formed in the trenches prior to metallization and can include, e.g., TiN, TaN, or similar materials. The metal lines 156 can include materials, such as, e.g., Cu, Ru, Mo, Rh, W, Ir, and alloys or combinations of these and other conductive materials. In a particularly useful embodiment, the metal lines 156 include Ru. The metal lines 156 can be formed using a deposition method, such as, e.g., CVD, PECVD, ALD or any other suitable deposition method. The metal lines 156 can be planarized, e.g., by CMP. The metal lines 156 can be considered a first metal layer M1. Additional dielectric layers 164 and 166 can be formed followed by corresponding metal structures, which can include metal layers M2, M3, . . . Mx labeled as metal lines 158, 160, 162, respectively. In addition, vias, e.g., vias 172, 174, which connect metal lines are also formed.

The metallization structures for a frontside BEOL layer 180 are formed to make connections to gates, source/drain regions 122 and other structures. The BEOL layer 180 can include additional levels of vias and metal lines as needed to complete the frontside of the wafer 100.

After part or all of the formation of the BEOL layer 180, a frontside super via is formed. An etch mask is formed by depositing a mask material 168 over the wafer 100. In an embodiment, the mask material can include an organic planarizing layer (OPL), which can be patterned using a lithographic patterning process. An etch process is performed to open up a super via opening 170. The super via opening 170 is etched using an anisotropic etch process, such as, e.g., RIE. The etch process etches through dielectric layers 154, 164, 166 and layers of metal lines 156, 158, 160, 162 to expose the contact 152 in the thermal conductor region 102.

Referring to FIG. 5, in an embodiment, a capacitor dielectric 176 is formed by adjusting etch chemistry to remove material of the metal lines with which the super via opening 170 traverses and intersects with. In this example, metal lines 156 and 160 are crossed by the super via opening 170. The etch process laterally etches the metal lines 156 and 160 that are exposed within the super via opening 170. Indentations formed by recessing the metal lines 156 and 160 are filled with a dielectric material. The dielectric material can be formed in a process similar to forming inner spacers and can be deposited by a selective deposition process or by a conformal deposition and etch process. The dielectric material forms the capacitor dielectric 176 or insulator. The capacitor dielectric 176 can include a nitride, or other high dielectric constant material. The capacitor dielectric 176 can have its thickness adjusted in accordance with the lateral recess of the metal lines 156, 160. In this way, properties of the capacitor or capacitors formed later can be accurately controlled. The material selection for the capacitor dielectric 176 can also contribute to the capacitor properties.

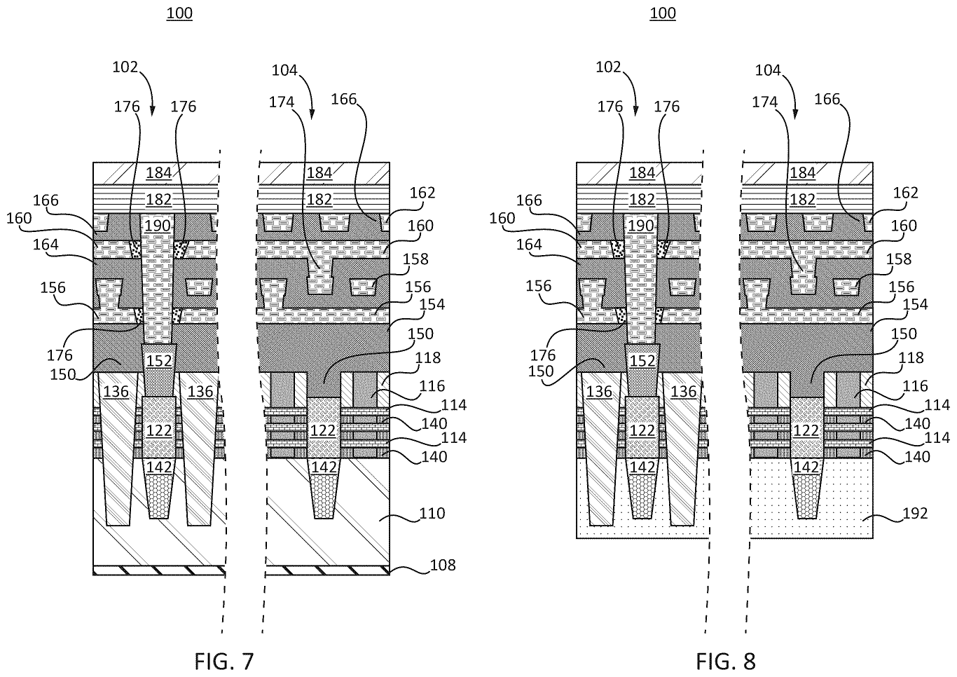

Referring to FIG. 6, a frontside super via 190 is formed in the thermal conductor region 102 by a conductive fill to make a connection with the contact 152. Prior to the conductive fill, the mask material 168 can be removed to expose trenches in the dielectric layer 166. A diffusion barrier (not shown) can be formed over the dielectric layer 166 and in the super via opening 170. The diffusion barrier can include, e.g., TiN, TaN, or similar materials. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP. In an embodiment, the conductive fill forms the frontside super via 190 and can form a top metal layer (Mx) 162. Processing can continue with the formation of the rest of a BEOL layer 182. The BEOL layer 182 can include metal structures embedded in dielectric materials. The frontside super via 190 connects to components within the BEOL layer 182 to permit heat transfer to the BEOL layer 182 during operation of the semiconductor device of the wafer 100.

In addition, the frontside super via 190 forms an electrode of a capacitor, e.g., a MIM capacitor, where the other electrode includes portions of metal lines 156 and 160, and the insulator includes the capacitor dielectric 176. A carrier wafer 184 can be bonded to the wafer 100 on the BEOL layer 182. The carrier wafer 184 provides support and transportability to the wafer 100 for further processing which includes flipping the wafer 100 and removing portions of a bottom side.

Referring to FIG. 7, the wafer 100 can be flipped to process features on the bottom side. However, for clarity and consistency, the wafer 100 will be shown in the FIGS. in a same orientation as previously described with continued and consistent reference to bottom/top. The substrate 106 is removed from the bottom side of the wafer 100. The substrate 106 is removed from the bottom side of the wafer 100. The substrate 106 can be removed by an etch process that stops on the etch stop layer 108. In an embodiment, the substrate 106 can be ground down, polished (e.g., CMP) and wet etched to the etch stop layer 108.

Referring to FIG. 8, the etch stop layer 108 is then removed by an etch process. In an alternate embodiment, a CMP process can be employed. With the removal of the etch stop layer 108, the semiconductor layer 110 is exposed. The semiconductor layer 110 is removed by an etch process that selectively removes the material of the semiconductor layer 110. The etch of the semiconductor layer 110 is performed selective to the sacrificial placeholders 142 and the dielectric material of the SDB 136. The removal of the semiconductor layer 110 leaves a void in regions around the sacrificial placeholders 142.

A backside interlayer dielectric (BILD) 192 is formed to replace the semiconductor layer 110 that was removed. The BILD 192 can be formed in accordance with the same of different processes and ILD 148 or ILD 150 and can include a same or different material. The BILD 192 can be planarized, e.g., by CMP.

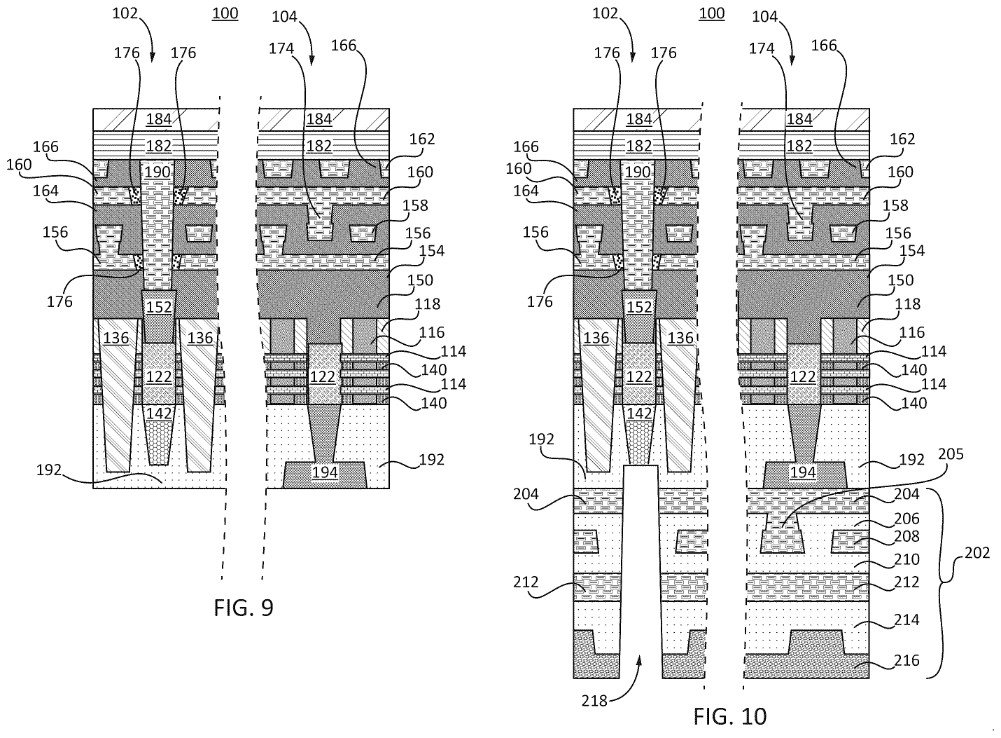

Referring to FIG. 9, the sacrificial placeholders 142 are exposed from the bottom (backside) by forming an etch mask (not shown) in the logic region 104 (and blocking off the thermal conductor region 102) and etching through the BILD 192. The sacrificial placeholders 142 in the logic region 104 are removed by etching to expose the source/drain region 122 in the logic region 104.

Contact formation can begin by forming a silicide liner (not shown), such as Ti, Ni, NiPt, which is deposited first, then a diffusion barrier (not shown) can be formed in the openings left by removing the sacrificial placeholders 142 prior to a conductive fill. The diffusion barrier can include, e.g., TiN, TaN, or similar materials. A conductive fill is performed to fill the openings. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form backside contacts 194.

The backside contacts 194 take on the profile of the contact openings. The backside contacts 194 include a tapered profile getting narrower to a point where the backside contact exceeds a width of the source/drain regions 122.

Referring to FIG. 10, an additional deposition extends the BILD 192. The additional deposition can include the same materials or different materials than the BILD 192. The additional deposition can be planarized, e.g., by CMP. The additional deposition is patterned and etched to form trenches for metal lines to be formed. A diffusion barrier (not shown) can be formed in the trenches formed in the additional deposition prior to a conductive fill. The diffusion barrier can include, e.g., TiN, TaN, or similar materials. A conductive fill is performed to fill the trenches. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form metal lines 204.

The metal lines 204 can be considered a first metal layer, M1. Additional dielectric layers 206, 210, 214, etc. can be formed followed by corresponding metal structures, which can include metal layers M2, M3, . . . Mx labeled as metal lines 208, 212, etc., respectively. In addition, vias, e.g., vias 205, which connect metal lines are also formed.

The metallization structures for a backside power distribution network (BSPDN) 202 or backside interconnect metallization layer are formed to make connections to devices from the backside of the wafer 100. The BSPDN 202 can include additional levels of vias and metal lines as needed to complete the backside of the wafer 100.

After part or all of the formation of the BSPDN 202, a backside super via is formed. An etch mask is formed by depositing a mask material 216 over the wafer 100. In an embodiment, the mask material 216 can include an organic planarizing layer (OPL), which can be patterned using a lithographic patterning process. An etch process is performed to open up a super via opening 218. The super via opening 218 is etched using an anisotropic etch process, such as, e.g., RIE. The etch process etches through dielectric layers 192, 206, 210, 214, etc. and layers of metal lines 204, 208, 212, etc. to expose the sacrificial placeholder 142 in the thermal conductor region 102.

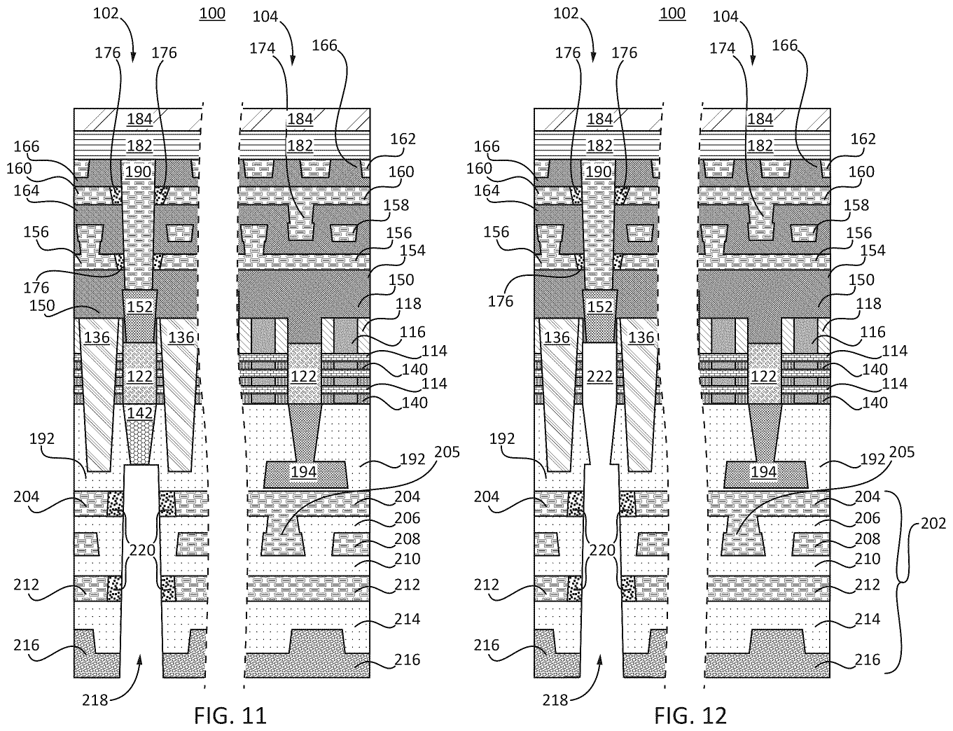

Referring to FIG. 11, in an embodiment, a capacitor dielectric 220 is formed by adjusting etch chemistry to remove material of the metal lines with which the super via opening 218 traverses and intersects with, in this example, metal lines 204 and 212 are crossed. The etch process laterally etches the metal lines 204 and 212 that are exposed within the super via opening 218. Indentations formed by recessing the metal lines 204 and 212 are filled with a dielectric material. The dielectric material can be formed in a process similar to forming inner spacers and can be deposited by a selective deposition process or by a conformal deposition and etch process. The dielectric material forms the capacitor dielectric 220 or insulator. The capacitor dielectric 220 can include a nitride, or other high dielectric constant material. The capacitor dielectric 220 can have its thickness adjusted in accordance with the lateral recess of the metal lines 204, 212. While the materials and structure of the capacitor dielectric 220 can be the same as for the capacitor dielectric 176, the thickness and materials of the capacitor dielectric 220 can be different than the thickness and materials for the capacitor dielectric 176. Properties of the capacitor or capacitors can be accurately controlled. The material selection for the capacitor dielectric 220 can also contribute to the capacitor properties.

Referring to FIG. 12, in the thermal conductor region 102, the sacrificial placeholder 142 is exposed within the super via opening 218. An etch process, such as, e.g., a self-aligned RIE, can be employed to remove the sacrificial placeholder 142. The same or a different etch chemistry can be employed to remove the source/drain region 122 from with the thermal conductor region 102. The source/drain region 122 removal exposes the contact 152 and forms a void 222 between the SDBs 136.

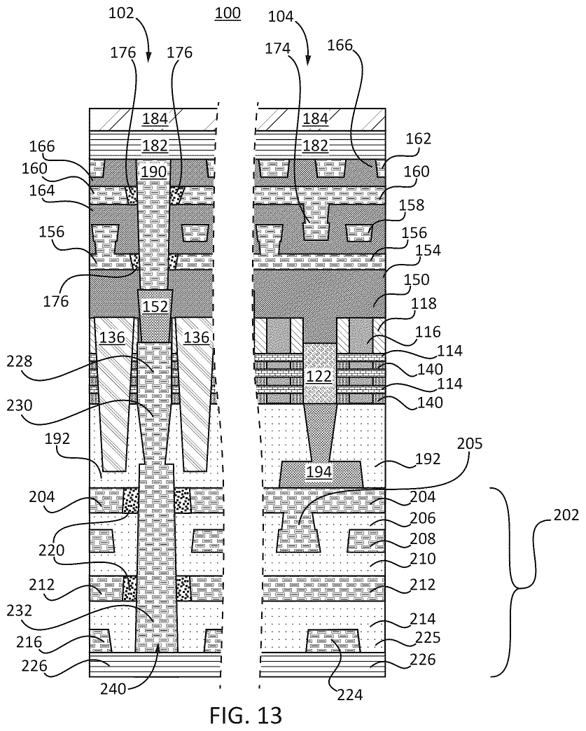

Referring to FIG. 13, a backside super via 232 is formed in the thermal conductor region 102 by a conductive fill to make a connection with the contact 152. Prior to the conductive fill, the mask material 216 can be removed to expose trenches in a dielectric layer 225. A diffusion barrier (not shown) can be formed over the dielectric layer 225 and in the super via opening 218 and void 222. The diffusion barrier can include, e.g., TiN, TaN, or similar materials. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP.

The conductive fill can form a conductor 228 that replaces the removed source/drain region 122. The conductor 228 spans a depth of the removed source/drain region 122. The conductive fill can form a tapered conductor 230 that replaces the removed sacrificial placeholder 142. The conductor 228 and the tapered conductor 230 can be formed in a same or different conductive fill processes. The tapered conductor 230 can have a same tapered direction as the frontside super via 190, e.g., larger on the frontside than the backside.

In an embodiment, the conductive fill forms the backside super via 232 and can form a top metal layer (Mx) 224 as well. The backside super via 232 can be formed in a same or different conductive fill process as conductor 228 and/or the tapered conductor 230. Processing can continue with the formation of a remaining portion 226 of the BSPDN 202. The remaining portion 226 can include metal structures embedded in dielectric materials.

The backside super via 232 connects to components within the BSPDN 202 to permit heat transfer to the BSPDN 202 during operation of the semiconductor device of the wafer 100. In addition, the backside super via 232 forms an electrode of a capacitor, e.g., a MIM capacitor, where the other electrode includes portions of metal lines 204 and 212, and the insulator includes the capacitor dielectric 220.

In accordance with embodiments of the present invention, a thermal conductivity channel 240 (super via chain) is formed that passes through a semiconductor device from a frontside to a backside. The thermal conductivity channel 240 includes the frontside super via 190, the backside super via 232, which are joined in a middle portion of the semiconductor device by the contact 152, the conductor 228 and the tapered conductor 230. The thermal conductivity channel 240 can extend between BEOL structurers on the frontside and the BSPDN on the backside. The thermal conductor region 102 where the thermal conductivity channel 240 is located can have its position determined based on heat transfer needs and can be located within an active region. In one example, the thermal conductor region 102 with the thermal conductivity channel 240 is placed adjacent to or within the logic region 104 where transistor devices or other heat producing devices are located.

By providing better thermal conductivity, better device performance can be achieved. The thermal conductivity channel 240 includes high thermally conductive materials to provide a controlled heat transfer path through a center portion of the semiconductor device to permit heat dissipation or over a distributed area of the BEOL structures and the BSPDN.

The thermal conductivity channel 240 can also form a metal-insulator-metal (MIM) capacitor when the thermal conductivity channel passes through metal levels. The thermal conductivity channel 240 can act as a capacitor electrode, and, e.g., the layers of metal lines 156, 160, 204, 212 can act as another electrode (or electrodes).

Referring to FIG. 14, another embodiment includes a stacked FET structure. A stacked FET structure includes two or more FETs stacked vertically. A layer stack or stacks are applied (e.g., bonded) to or formed on a first level 115. In an embodiment, a nanosheet (NS) is applied to the first level 115 and is employed to form another gate structure 326 on a second level 215 similar to the gate structure 124 for the first level 115. The gate structure 326 can include RMG structures and include a gate electrode 316 similar to gate electrode 116.

In an embodiment, the layer stack of the nanosheet includes channels 314 for the second level 215 of field effect transistors (FETs) in alternating layers of the nanosheet. The other alternating layers can include a different material than the channels 314. For example, if the channels 314 include Si, the alternating layers can include SiGe. A dielectric layer 327, such as a middle dielectric isolation (MDI) is formed between gate structures 124 and gate structures 324. The dielectric layer 327 can include, e.g., an oxide.

The alternating layers are recessed and filled with a dielectric material to form inner spacers 340. The inner spacers 340 can be formed by filling recesses where nanosheet layers were removed (by etching) with a dielectric material, e.g., SiBCN, SiCN or other suitable dielectric materials. Outer spacers 318 are formed by a spacer formation process (similar to spacers 118). A dielectric plug 325 is formed over the source/drain regions 122. Source/drain regions 322 are formed over the source/drain regions 122. The source/drain regions 322 can be grown using an epitaxial growth process using the channels 314 to initiate crystal growth.

The source/drain regions 322 can include Si or SiGe. In an embodiment, the source/drain regions 322 can be designated as P-type or N-type devices. For example, if the source/drain regions 322 include N-type devices then the source/drain regions 322 can include Si. In another example, if the source/drain regions 322 include P-type devices then the source/drain regions 322 can include SiGe. The source/drain regions 322 can be appropriately doped during their formation. For example, the source/drain regions 322 can be doped by introducing p dopants (e.g., B, Ga, etc.) during epitaxial formation. Similarly, the source/drain regions 322 can be doped by introducing n dopants (e.g., P, As, etc.) during epitaxial formation.

The ILD 150 is patterned by forming an etch mask and etching (e.g., RIE) contact openings in the ILD 150. The patterning of the ILD 150 is concurrently performed in the thermal conductor region 102 and the logic region 104. Middle of the line (MOL) contacts 152 and 352 are concurrently formed in the thermal conductor region 102 and the logic region 104 by a conductive fill to make connections with the source/drain regions 322 (and/or the gate electrodes 316) from a top or frontside of the wafer 100. Prior to the conductive fill, a silicide liner (not shown), such as Ti, Ni, NiPt can be deposited first, then a diffusion barrier (not shown) can be formed. The diffusion barrier can include, e.g., TiN, TaN, or similar materials. The silicide liner and the diffusion barrier can be deposited in the trench or hole (e.g., by ALD). The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the contacts 352.

BEOL structures are now formed as described in the BEOL layer 180. After part or all of the formation of the BEOL layer 180, the frontside super via 190 is formed.

The capacitor dielectric 176 is formed. The capacitor dielectric 176 can have its thickness adjusted in accordance with the lateral recess of the metal lines 156, 160. In this way, properties of the capacitor or capacitors formed later can be accurately controlled. The material selection for the capacitor dielectric 176 can also contribute to the capacitor properties.

The frontside super via 190 is formed in the thermal conductor region 102 by a conductive fill to make a connection with the contact 352. A diffusion barrier (not shown) can be formed before the conductive fill. The conductive fill is planarized, e.g., by CMP. The frontside super via 190 connects to components within the BEOL layer 182 to permit heat transfer to the BEOL layer 182 during operation of the semiconductor device of the wafer 100.

In addition, the frontside super via 190 forms an electrode of a capacitor, e.g., a MIM capacitor, where the other electrode includes portions of metal lines 156 and 160 and the insulator includes the capacitor dielectric 176. A carrier wafer 184 can be bonded to the wafer 100 on the BEOL layer 182. The carrier wafer 184 provides support and transportability to the wafer 100 for further processing which includes flipping the wafer 100 and removing portions of a bottom side.

The wafer 100 can be flipped to process features on the bottom or backside. However, for clarity and consistency, the wafer 100 will be shown in the FIGS. in a same orientation as previously described with continued and consistent reference to bottom/top. A substrate is removed from the bottom side of the wafer 100. The substrate is removed from the bottom side of the wafer 100.

The BILD 192 is formed to replace removed portions. The BILD 192 can be planarized, e.g., by CMP. The BILD 192 is etched and the backside contact 194 is formed.

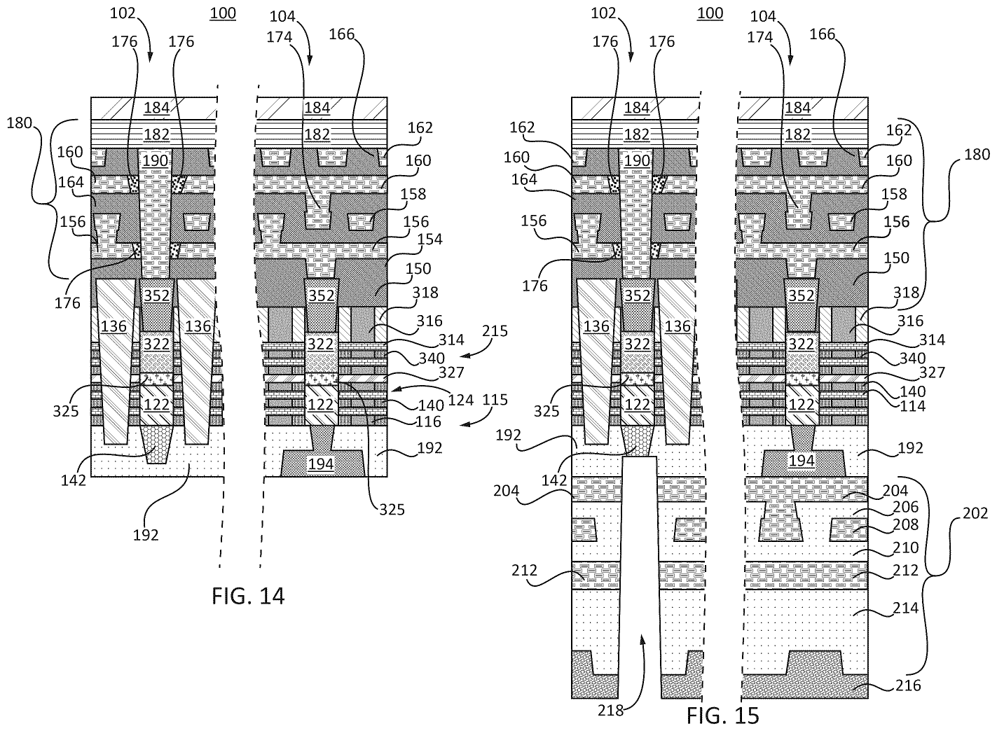

Referring to FIG. 15, the BSPDN 202 is fully or partially formed. The sacrificial placeholders 142 are exposed from the bottom side by forming an etch mask (not shown) in the thermal conductor region 102 and etching through the BILD 192 and layers of the BSPDN 202. The backside super via opening 218 is formed. The super via opening 218 is etched using an anisotropic etch process, such as, e.g., RIE. The etch process etches through dielectric layers 192, 206, 210, 214, etc. and layers of metal lines 204, 208, 212, etc. to expose the sacrificial placeholder 142 in the thermal conductor region 102.

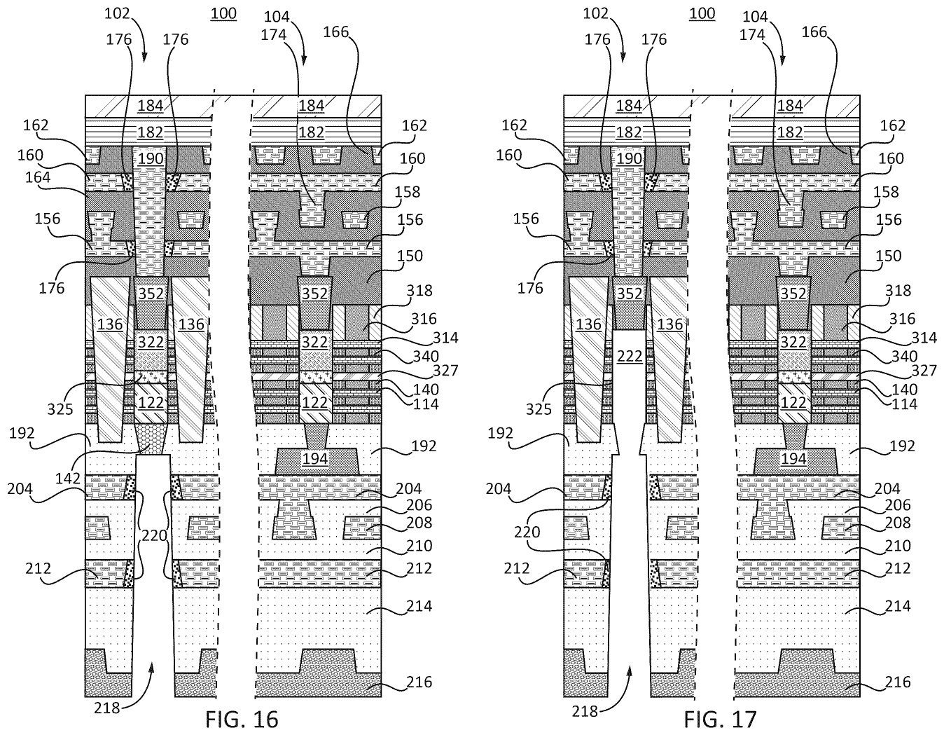

Referring to FIG. 16, in an embodiment, the capacitor dielectric 220 is formed by adjusting etch chemistry to remove material of the metal lines with which the super via opening 218 traverses and intersects with, in this example, metal lines 204 and 212 are crossed. The etch process laterally etches the metal lines 204 and 212 that are exposed within the super via opening 218. Indentations formed by recessing the metal lines 204 and 212 are filled with a dielectric material. The capacitor dielectric 220 can have its thickness adjusted in accordance with the lateral recess of the metal lines 204, 212. While the materials and structure of the capacitor dielectric 220 can be the same as for the capacitor dielectric 176, the thickness and materials of the capacitor dielectric 220 can be different than the thickness and materials for the capacitor dielectric 176. Properties of the capacitor or capacitors can be accurately controlled. The material selection for the capacitor dielectric 220 can also contribute to the capacitor properties.

Referring to FIG. 17, in the thermal conductor region 102, the sacrificial placeholder 142 is exposed within the super via opening 218. An etch process, such as, e.g., a self-aligned RIE, can be employed to remove the sacrificial placeholder 142. The same of a different etch chemistry can be employed to remove the source/drain region 122 from with the thermal conductor region 102. The dielectric plug 325 is removed followed by the removal of the source/drain region 322 to expose the contact 352 and form the void 222 between the SDBs 136.

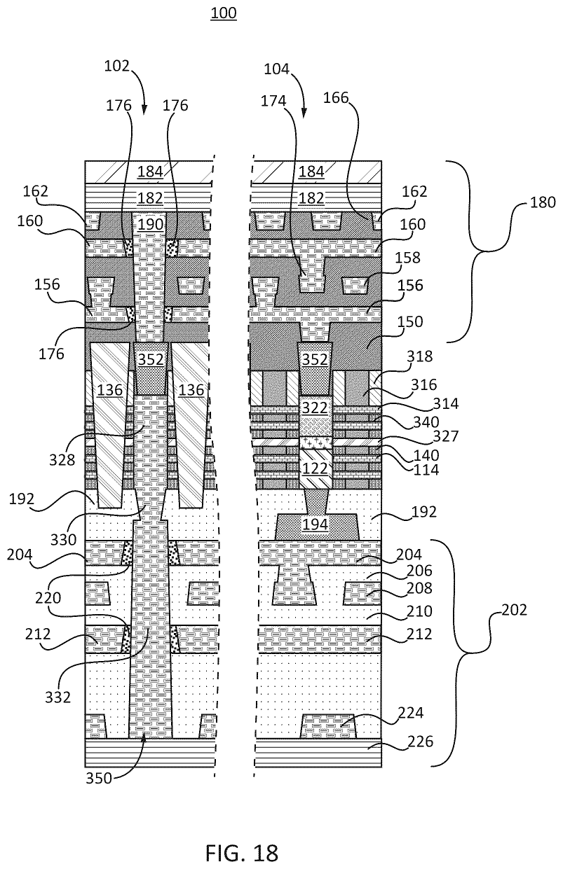

Referring to FIG. 18, a backside super via 332 is formed in the thermal conductor region 102 by a conductive fill to make connection with the contact 352. Prior to the conductive fill, a diffusion barrier (not shown) can be formed in the super via opening 218 and void 222. The diffusion barrier can include, e.g., TiN, TaN, or similar materials. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP.

The conductive fill can form a conductor 328 that replaces the removed source/drain region 322. The conductor 328 spans a depth of the removed source/drain regions 122 and 322 (or more layers of source/drain regions, if present). The conductive fill can form a tapered conductor 330 that replaces the removed sacrificial placeholder 142. The conductor 328 and the tapered conductor 330 can be formed in a same or different conductive fill processes. The tapered conductor 330 can have a same tapered direction as the frontside super via 190, e.g., larger on the frontside than the backside. Processing can continue with the formation of a remaining portion 226 of the BSPDN 202. The remaining portion 226 can include metal structures embedded in dielectric materials.

The backside super via 332 connects to components within the BSPDN 202 to permit heat transfer to the BSPDN 202 during operation of the semiconductor device of the wafer 100. In addition, the backside super via 332 forms an electrode of a capacitor, e.g., a MIM capacitor, where the other electrode includes portions of metal lines 204 and 212 and the insulator includes the capacitor dielectric 220.

In accordance with embodiments of the present invention, a thermal conductivity channel 350 (super via chain) is formed that passes through a semiconductor device from a frontside to a backside. The thermal conductivity channel 350 includes the frontside super via 190, the backside super via 332, which are joined in a middle portion of the semiconductor device by the contact 352, the conductor 328 and the tapered conductor 330. The thermal conductivity channel 350 can extend between BEOL structures on the frontside and the BSPDN on the backside. The thermal conductor region 102 where the thermal conductivity channel 350 is located can have its position determined based on heat transfer needs and can be located within an active region. In one example, the thermal conductor region 102 with the thermal conductivity channel 350 is placed adjacent to or within the logic region 104 where transistor devices or other heat producing devices are located.

By providing better thermal conductivity, better device performance can be achieved. The thermal conductivity channel 350 includes high thermally conductive materials to provide a controlled heat transfer path through a center portion of the semiconductor device to permit heat dissipation or over a distributed area of the BEOL structures and the BSPDN.

The thermal conductivity channel 350 can also form a metal-insulator-metal (MIM) capacitor when the thermal conductivity channel passes through metal levels. The thermal conductivity channel 350 can act as a capacitor electrode, and, e.g., layers of metal lines 156, 160, 204, 212 can act as another electrode (or electrodes).

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled”to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a back end of the line region on a frontside of the semiconductor device;
a backside interconnect metallization layer on a backside of the semiconductor device; and
a thermal conductivity channel disposed between the back end of the line region and the backside interconnect metallization layer, the thermal conductivity channel including a frontside super via and a backside super via connected by a contact therebetween.

2. The semiconductor device as recited in claim 1, wherein the thermal conductivity channel is disposed within a thermal conductor region adjacent to a logic region to channel heat to the back end of the line region and the backside interconnect metallization layer.

3. The semiconductor device as recited in claim 1, wherein the thermal conductivity channel includes a middle portion having a tapered conductor.

4. The semiconductor device as recited in claim 3, wherein the frontside super via and the tapered conductor are tapered in a same direction.

5. The semiconductor device as recited in claim 3, further comprising single diffusion barriers formed on opposite side of the middle portion.

6. The semiconductor device as recited in claim 3, wherein the middle portion includes an additional conductor connected between the tapered conductor and the frontside super via.

7. The semiconductor device as recited in claim 6, wherein the additional conductor spans a depth of a single source/drain region.

8. The semiconductor device as recited in claim 6, wherein the additional conductor spans a depth of a plurality of source/drain regions.

9. The semiconductor device as recited in claim 1, wherein the thermal conductivity channel is an electrode of a capacitor.

10. A semiconductor device, comprising:
a back end of the line region on a frontside of the semiconductor device;
a backside interconnect metallization layer on a backside of the semiconductor device;
a thermal conductivity channel disposed between the back end of the line region and the backside interconnect metallization layer, the thermal conductivity channel including a frontside super via and a backside super via connected by a contact therebetween; and
a capacitor including the thermal conductivity channel as a first electrode and metal lines traversed by the thermal conductivity channel as a second electrode.

11. The semiconductor device as recited in claim 10, wherein the thermal conductivity channel is disposed within a thermal conductor region adjacent to a logic region to channel heat to the back end of the line region and the backside interconnect metallization layer.

12. The semiconductor device as recited in claim 10, wherein the thermal conductivity channel includes a middle portion having a tapered conductor.

13. The semiconductor device as recited in claim 12, wherein the frontside super via and the tapered conductor are tapered in a same direction.

14. The semiconductor device as recited in claim 12, further comprising single diffusion barriers formed on opposite side of the middle portion.

15. The semiconductor device as recited in claim 12, wherein the middle portion includes an additional conductor connected between the tapered conductor and the frontside super via.

16. The semiconductor device as recited in claim 15, wherein the additional conductor spans a depth of a single source/drain region.

17. The semiconductor device as recited in claim 15, wherein the additional conductor spans a depth of a plurality of source/drain regions.

18. The semiconductor device as recited in claim 10, further comprising a capacitor dielectric disposed within indentations of the metal lines and adjacent to the thermal conductivity channel.

19. A semiconductor device, comprising:
a back end of the line region on a frontside of the semiconductor device;
a backside interconnect metallization layer on a backside of the semiconductor device;
a thermal conductivity channel disposed between the back end of the line region and the backside interconnect metallization layer, the thermal conductivity channel including a frontside super via and a backside super via connected by a contact therebetween, the thermal conductivity channel being disposed within a thermal conductor region adjacent to a logic region to channel heat to the back end of the line region and the backside interconnect metallization layer; and
a capacitor including:
a first electrode as the thermal conductivity channel;
metal lines traversed by the thermal conductivity channel as a second electrode; and
a capacitor dielectric disposed within indentations of the metal lines and adjacent to the thermal conductivity channel.

20. The semiconductor device as recited in claim 19, wherein the thermal conductivity channel includes a middle portion having a tapered conductor having a same tapered direction as the frontside super via and an additional conductor connected between the tapered conductor and the frontside super via that spans a depth of at least one single source/drain region.
